(19) United States
(12) Patent Application Publication
(10) Pub. No.: US 2026/0306994 A1
(43) Pub. Date: Oct. 8, 2026

(54) MACHINE LEARNING MODEL INCORPORATING PHYSICAL FEATURES OF SORBENTS FOR POST COMBUSTION CARBON CAPTURE

(71) Applicant: GE Vernova Infrastructure Technology LLC, Greenville, SC (US)

(72) Inventors: Soumya CHAKRABORTY, Bengaluru (IN); Albert S. STELLA, Niskayuna, NY (US); Mohandas NAYAK, Bengaluru (IN); Amit GAIKWAD, Bengaluru (IN)

(21) Appl. No.: 19/485,119

(22) PCT Filed: May 26, 2023
(86) PCT No.: PCT/US2023/023746

§ 371 Date: Nov. 17, 2025

(51) Int. Cl. B01D 53/04; G06F 17/18; G06N 20/00

(52) U.S. Cl. CPC B01D 53/0454; G06F 17/18; G06N 20/00

(57) ABSTRACT

A power generation system including a capture system for use in capturing carbon dioxide, a controller configured to operate the capture system, and a modeling system including a processor is provided. The processor is configured to identify a model training data set, each instance of the model training data set identifying a sorbent used by the capture system, a carbon capture performance value for the sorbent, and a plurality of primary feature values associated with a plurality of primary features, generate one or more secondary features based on one or more of the plurality of primary features, generate a transfer function, and determine, using the transfer function, one or more prospective sorbents to be used by the capture system. The controller operates the capture system using the one or more prospective sorbents determined by the modeling system.

### TECHNICAL FIELD

The present application relates generally to modeling post combustion carbon capture systems, and more particularly, to systems and methods for modeling expected performance of novel sorbents, specifically metal organic frameworks, in a post combustion carbon capture system and for operating the post combustion carbon capture system using one or more prospective sorbents based on a carbon capture performance value as determined by the modeling.

### BACKGROUND

Some power plant systems may include post combustion carbon capture (“PCC”) systems that are configured to capture carbon dioxide (CO₂) from the waste gas (flue gas) produced. PCC systems may be used to capture CO₂ from the waste gas produced by power plants that include, for example, coal-burning systems, gas turbines, and/or boilers. Some types of PCC systems use metal-organic frameworks (“MOFs”) to facilitate carbon capture. Metal-organic frameworks typically include two main components, an inorganic metal constituent (often called a secondary building unit, or “SBU”) and an organic constituent (often called a “linker”). Various different MOFs have been developed and tested for their capture capacity (e.g., a measure of how effective a particular MOF performs at capturing CO₂). However, there are potentially millions of combinations of metals, linkers, and other functional groups that could be employed in an MOF, some of which could yield greater capture capacity and productivity than existing MOFs, and the real-world creation and study of each possible combination of constituents is economically prohibitive.

What is needed is a system and method for modeling MOF performance using known MOFs in order to predict how other proposed MOFs may perform and adjust the operation of a carbon capture system to use a MOF based on the predicted carbon capture performance.

### SUMMARY

In one aspect, a power generation system is provided. The power generation system includes a capture system for use in capturing carbon dioxide, a controller configured to operate the capture system, and a modeling system including a processor. The processor is configured to identify a model training data set, each instance of the model training data set identifying a sorbent used by the capture system, a carbon capture performance value for the sorbent, and a plurality of primary feature values associated with a plurality of primary features. The processor is also configured to generate one or more secondary features based on one or more of the plurality of primary features, each of the one or more secondary features being a combination of at least two of the plurality of primary features, and determine a plurality of correlation magnitude values including a correlation magnitude value between each of the plurality of primary features and each of the one or more secondary features. The processor is also configured to identify a first subset of the model training data set based on the plurality of correlation magnitude values, determine a statistical significance for each instance of the first subset of the model training data set, and identify a second subset of the model training data set based on the statistical significance, wherein the statistical significance for each instance of the second subset of the model training data set is below a pre-determined threshold. The processor is further configured to generate a transfer function based on the second subset of the model training data set, and determine, using the transfer function, one or more prospective sorbents to be used by the capture system based on the carbon capture performance value. The controller operates the capture system using the one or more prospective sorbents determined by the modeling system.

In another aspect, a method of selecting one or more prospective sorbents for use in operating a capture system to capture carbon dioxide. The method comprises identifying a model training data set, each instance of the model training data set identifying a sorbent used by the capture system, a carbon capture performance value for the sorbent, and a plurality of primary feature values associated with a plurality of primary features. The method also comprises generating one or more secondary features based on one or more of the plurality of primary features, each of the one or more secondary features being a combination of at least two of the plurality of primary features, determining a plurality of correlation magnitude values including a correlation magnitude value between each of the plurality of primary features and each of the one or more secondary features, and identifying a first subset of the model training data set based on the plurality of correlation magnitude values. The method also includes determining a statistical significance for each instance of the first subset of the model training data set, identifying a second subset of the model training data set based on the statistical significance, wherein the statistical significance for each instance of the second subset of the model training data set is below a pre-determined threshold, and generating a transfer function based on the second subset of the model training data set. The method further includes determining, using the transfer function, one or more prospective sorbents to be used by the capture system based on the carbon capture performance value, wherein a controller operates the capture system using the one or more prospective sorbents determined using the transfer function.

### BRIEF DESCRIPTION OF THE DRAWINGS

The subject-matter of the disclosure will be explained in more detail in the following text with reference to exemplary embodiments which are illustrated in the attached drawings.

FIG. 1 illustrates an example PCC modeling system that can be used to anticipate how particular MOFs may perform in capturing carbon dioxide (CO₂) from exhaust gases of a coal-fired power plant.

FIG. 2 is a graph that illustrates a drop in CO₂ adsorptive productivity for an example sorbent (e.g., an example MOF) when going from a synthesized powder measured under equilibrium conditions to a final film coating on a substrate measured under dynamic conditions.

FIGS. 3A-3C are a flow chart illustrating an example method for analyzing anticipated performance for prospective sorbents in post-combustion carbon capture systems.

FIG. 4 illustrates an example correlation matrix.

The reference symbols used in the drawings, and their meanings, are listed in summary form in the list of reference symbols. In principle, identical parts are provided with the same reference symbols in the figures.

### DETAILED DESCRIPTION

In the following specification and the claims, reference will be made to a number of terms, which shall be defined to have the following meanings.

As used herein, the singular forms “a,” “an,” and “the” include plural references unless the context clearly dictates otherwise. The terms “comprising,” “including,” and “having” are intended to be inclusive and mean that there may be additional elements other than the listed elements. The terms “optional” or “optionally” means that the subsequently described event or circumstance may or may not occur, and that the description includes instances where the event occurs and instances where it does not.

Unless otherwise indicated, approximating language, such as “generally,” “substantially,” and “about,” as used herein indicates that the term so modified may apply to only an approximate degree, as would be recognized by one of ordinary skill in the art, rather than to an absolute or perfect degree. Accordingly, a value modified by a term or terms, such as “about,” “approximately,” and “substantially,” is not to be limited to the precise value specified. In at least some instances, the approximating language may correspond to the precision of an instrument for measuring the value. Here and throughout the specification and claims, range limitations may be identified. Such ranges may be combined and/or interchanged, and include all the sub-ranges contained therein unless context or language indicates otherwise.

Additionally, unless otherwise indicated, the terms “first,” “second,” etc. are used herein merely as labels, and are not intended to impose ordinal, positional, or hierarchical requirements on the items to which these terms refer. Moreover, reference to, for example, a “second” item does not require or preclude the existence of, for example, a “first” or lower-numbered item or a “third” or higher-numbered item.

In one embodiment, a computer program is provided, and the program is embodied on a computer readable medium. In the exemplary embodiment, the system is executed on a single computer system, without requiring a connection to a sever computer. In a further embodiment, the system is being run in a Windows® environment (Windows is a registered trademark of Microsoft Corporation, Redmond, Washington). In yet another embodiment, the system is run on a mainframe environment and a UNIX® server environment (UNIX is a registered trade-mark of X/Open Company Limited located in Reading, Berkshire, United Kingdom). In a further embodiment, the system is run on an iOS® environment (iOS is a registered trademark of Cisco Systems, Inc. located in San Jose, CA). In yet a further embodiment, the system is run on a Mac OS® environment (Mac OS is a registered trademark of Apple Inc. located in Cupertino, CA). In still yet a further embodiment, the system is run on Android® OS (Android is a registered trademark of Google, Inc. of Mountain View, CA). In another embodiment, the system is run on Linux® OS (Linux is a registered trademark of Linus Torvalds of Boston, MA). The application is flexible and designed to run in various different environments without compromising any major functionality. In some embodiments, the system includes multiple components distributed among a plurality of computing devices. One or more components may be in the form of computer-executable instructions embodied in a computer-readable medium.

As used herein, references to “example embodiment” or “one embodiment” of the present disclosure are not intended to be interpreted as excluding the existence of additional embodiments that also incorporate the recited features.

As used herein, the terms “software” and “firmware” are interchangeable, and include any computer program stored in memory for execution by a processor, including RAM memory, ROM memory, EPROM memory, EEPROM memory, and non-volatile RAM (NVRAM) memory. The above memory types are example only, and are thus not limiting as to the types of memory usable for storage of a computer program.

As used herein, a processor may include any programmable system including systems using micro-controllers, reduced instruction set circuits (RISC), application specific integrated circuits (ASICs), logic circuits, and any other circuit or processor capable of executing the functions described herein. The above examples are example only, and are thus not intended to limit in any way the definition and/or meaning of the term “processor.”

The systems and processes are not limited to the specific embodiments described herein. In addition, components of each system and each process can be practiced independent and separate from other components and processes described herein. Each component and process also can be used in combination with other assembly packages and processes.

As used herein, the term “non-transitory computer-readable media” is intended to be representative of any tangible computer-based device implemented in any method or technology for short-term and long-term storage of information, such as, computer-readable instructions, data structures, program modules and sub-modules, or other data in any device. Therefore, the methods described herein may be encoded as executable instructions embodied in a tangible, non-transitory, computer readable medium, including, without limitation, a storage device and/or a memory device. Such instructions, when executed by a processor, cause the processor to perform at least a portion of the methods described herein. Moreover, as used herein, the term “non-transitory computer-readable media” includes all tangible, computer-readable media, including, without limitation, nontransitory computer storage devices, including, without limitation, volatile and nonvolatile media, and removable and non-removable media such as a firmware, physical and virtual storage, CD-ROMs, DVDs, and any other digital source such as a network or the Internet, as well as yet to be developed digital means, with the sole exception being a transitory, propagating signal.

Embodiments of the invention relate generally to systems and methods for analyzing physical features of sorbents for post combustion carbon capture (“PCC”), and more particularly, to systems and methods for modeling aspects of metal-organic frameworks (“MOFs”) based on their constituents and their performance in capture capacity for carbon dioxide (CO₂). In example embodiments, a modeling system is configured to train a model based on performance characteristics of known metal-organic frameworks (“MOFs”) and their associated constituents. This model may then be used to evaluate the anticipated performance of other MOFs based on their particular constituents. Such modeling can help scientists and engineers evaluate different MOFs without having to physically test each candidate, thus leading to the quicker development of MOFs having improved performance in capture capacity for CO₂.

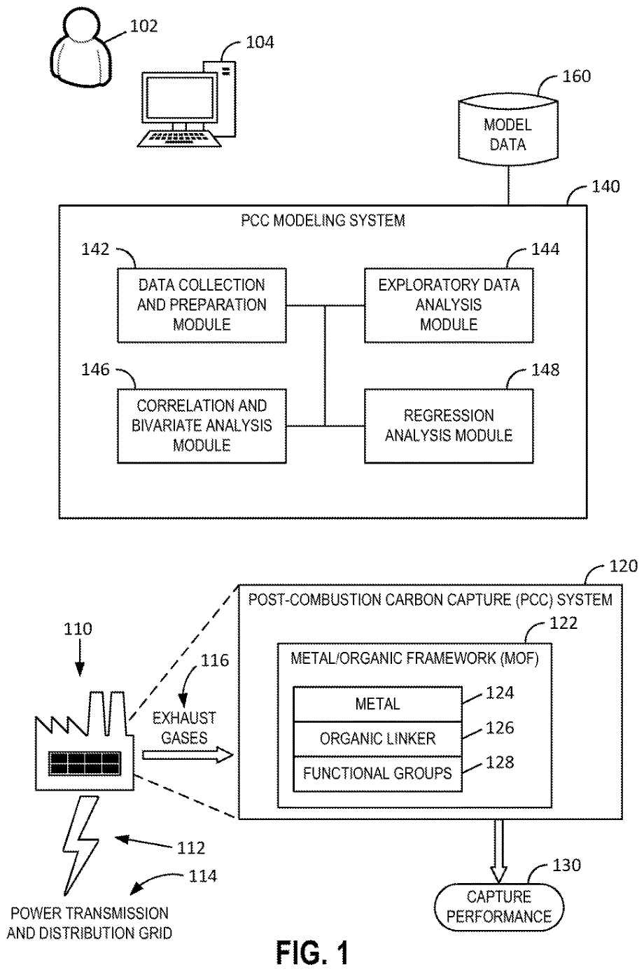

FIG. 1 illustrates an example PCC modeling system 140 that can be used to anticipate how particular MOFs may perform in capturing carbon dioxide (CO₂) from exhaust gases 116 of a coal-fired power plant 110. In the example embodiment, the power plant 110 generates electricity 112 that is distributed via a power transmission and distribution grid 114. The power plant 110 also includes a post-combustion carbon capture (PCC) system 120 that is configured to remove CO₂ from the exhaust gases 116 before the treated exhaust is released into the environment. The example PCC system 120 includes a metal-organic framework (MOF) 122 that performs the capturing functionality of the PCC system 120. The MOF 122 is comprised of three primary constituents, namely a metal 124, an organic linker 126, and one or more functional groups 128. During operation, the PCC system 120 yields some performance results, represented here generally as “capture performance” 130 (e.g., PCC capacity) for purposes of discussion. The PCC modeling system 140 is configured to estimate how particular MOFs (e.g., particular combinations of constituents and various associated physical features) would perform if implemented in the PCC system 120 (e.g., performance predictions in a “real world” setting).

In the example embodiment, the PCC modeling system 140 includes a data collection and preparation module 142 that is configured to identify and store data that will be used to train a machine learning model (e.g., a supervised forecasting model). The preparation module 142 stores historical records of various sorbents (e.g., MOFs 122) and their associated features and known performance. Each historical record can include, for example, sorbent data such as the constituents of the particular sorbent (e.g., information on the metal 124 used in the secondary building unit or SBU, information on the organic linker 126, and/or information on any functional groups 128 or amines associated with the particular MOF 122), various physical features of the sorbent (e.g., pore size, pore volume, pore size distribution, surface area, and the like), and known performance data for the sorbent (e.g., isosteric heat of adsorption (Q_{ST}), Henry's Law constant, selectivity ratio, sorbent capacity in millimoles of CO₂ per gram of sorbent, sorbent productivity in millimoles of CO₂ per gram of sorbent per unit time, or the like, at a particular pressure and/or temperature). Each of these historical records may be stored as model data 160 (e.g., in a database) and may include other data described herein. Some of these records may be collected from publication literature, where other records may include data collected from laboratory measured data or operational performance data of the PCC system 120 (e.g., data collected during operation).

The PCC modeling system 140 also includes an exploratory data analysis module 144 that is configured to help an analyst 102 perform univariate data analysis on aspects of the historical data. In an example embodiment, the exploratory data analysis module 144 is configured to generate graphs that display a single constituent of known MOFs against a single feature, thereby allowing the analyst 102 to see trends for the feature across various MOFs. For example, the analysis module 144 may generate a plot of chemisorbents and physisorbents, two types of MOFs, and how they perform with regard to Henry's constant, selectivity ratio, heat of adsorption, PCC capacity, and PCC productivity (e.g., as a composite across those two types of MOFs). In another example, the analysis module 144 may generate a plot of various metal types in physisorbent or chemisorbent MOFs and their respective adsorption heat (e.g., ranges of values, average value, or the like, for each metal type). These plots may be compiled and generated from the historical records identified in the model data 160 and displayed to the analyst 102 via a display of the computing device 104. From this data, the analyst 102 may further identify one or more second order features, which may be combinations of two or more of first order features, as discussed further below. Such second order features may be used in later model training and analysis.

The PCC modeling system 140, in the example embodiment, also includes a correlation and bivariate analysis module 146 that is configured to analyze the model data 160 with respect to positive or negative correlations between the pairs of various features of the historical records. For example, the analysis module 146 may identify a set of first order features, and perhaps one or more second order features, and perform a correlation analysis between the associated features. For each particular pairing of two features, the analysis module 146 computes a correlation coefficient (e.g., across all records in the model data 160) that identifies how those two features correlate with each other (e.g., where a positive coefficient indicates a positive correlation between the two features, and where a negative coefficient indicates a negative correlation between those two features). These correlation coefficients may be, for example, Pearson's correlation coefficients or the like. These correlation coefficients may be displayed to the analyst 102 in a matrix format, thereby allowing the analyst 102 to view the strengths of correlations between the various feature pairs. In some examples, the matrix may be a heat map that, for example, displays each correlation coefficient in a color of a color spectrum having strong positive correlations in a color at one end of the spectrum (e.g., dark blue) and having strong negative correlations in another color at the opposite end of the spectrum (e.g., dark red), being colored along the spectrum based on the magnitude of the correlation coefficient. In some examples, the analysis module 146 may generate pair plots for each of the feature pairs, thereby allowing the analyst 102 to evaluate what type of relationship the two features have (e.g., linear, non-linear, or such).

The PCC modeling system 140 also includes a regression analysis module 148 that is configured to perform regression analysis using the model data 160. In the example embodiment, the regression analysis module 148 identifies one or more features of interest for regression analysis. In some embodiments, the analyst 102 may inspect the correlation matrix and/or pair plots discussed above and may select a subset of features of interest. In some embodiments, the regression analysis module 148 may automatically identify one or more features of interest for the regression analysis (e.g., based on the correlation coefficients of the matrix). For example, the regression analysis module 148 may select all features that have a positive correlation coefficient with the PCC capacity above a particular threshold (e.g., strongly positively correlated). In some embodiments, the regression analysis module 148 may also select all features that have a negative correlation coefficient with the PCC capacity that is below a particular threshold (e.g., strongly negatively correlated). In some embodiments, the features that are used to start the regression analysis are manually selected, such as by a user.

Once a subset of features are identified, the regression analysis module 148 performs a regression analysis process starting with the subset of features. In some embodiments, a portion of the model data 160 may be automatically or manually identified as training data (e.g., to be used in this regression analysis process) and the remaining portion of the model data 160 may be reserved for evaluating the resulting model (e.g., 60% training data, 40% testing data). In the example embodiment, the regression analysis process is performed in one or more stages, where each stage includes performing multiple linear regression analyses on a current set of features. Based on the results at each stage, one or more features may be removed for a subsequent stage of analysis, leaving a further subset of down-selected features for the next stage of analysis until a particular stop criterion is achieved. At this final stage, the regression analysis module 148 generates a transfer function using the final remaining down-selected feature(s) (e.g., PCC capacity as a function the particular down-selected features). This transfer function thus can be applied to a new MOF, and its associated feature values, to anticipate how that novel MOF may perform with respect to PCC capacity, productivity, or the like.

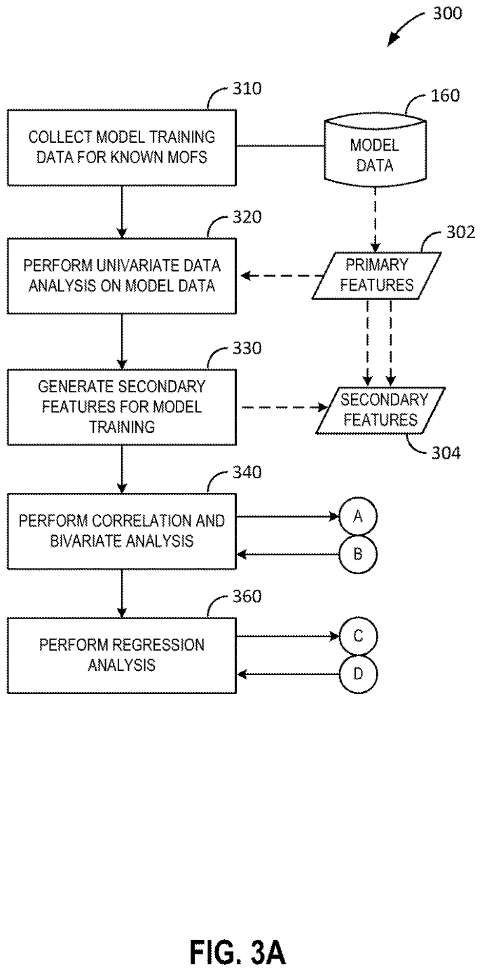

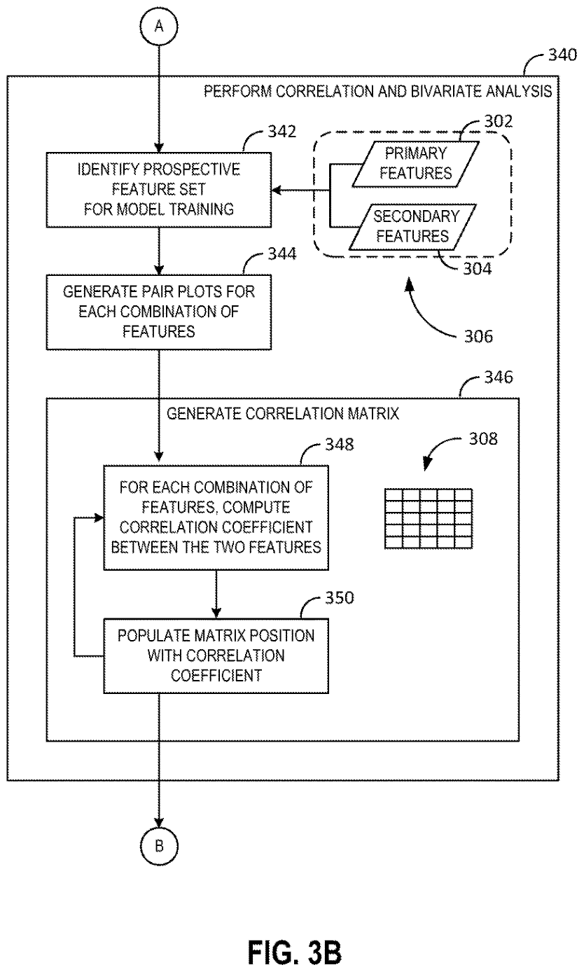

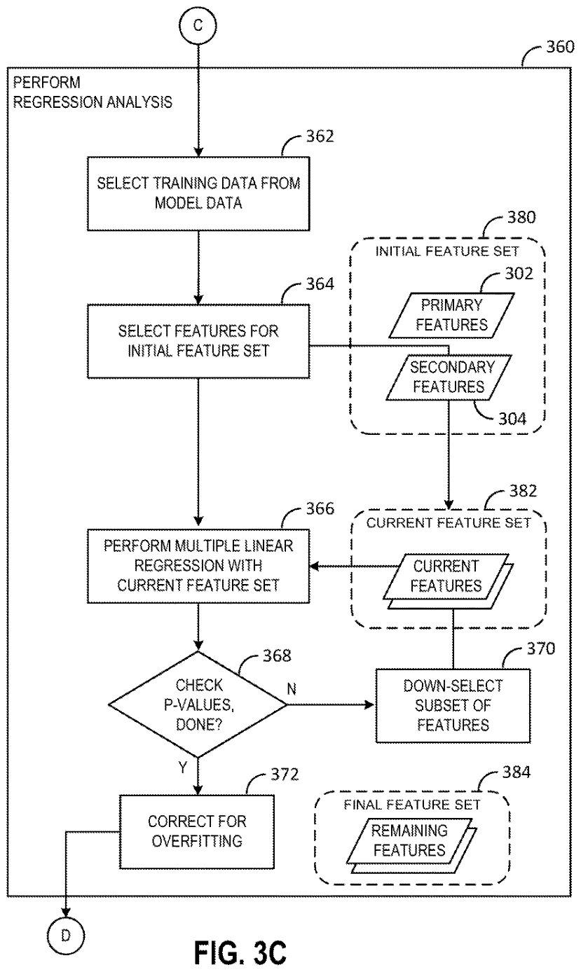

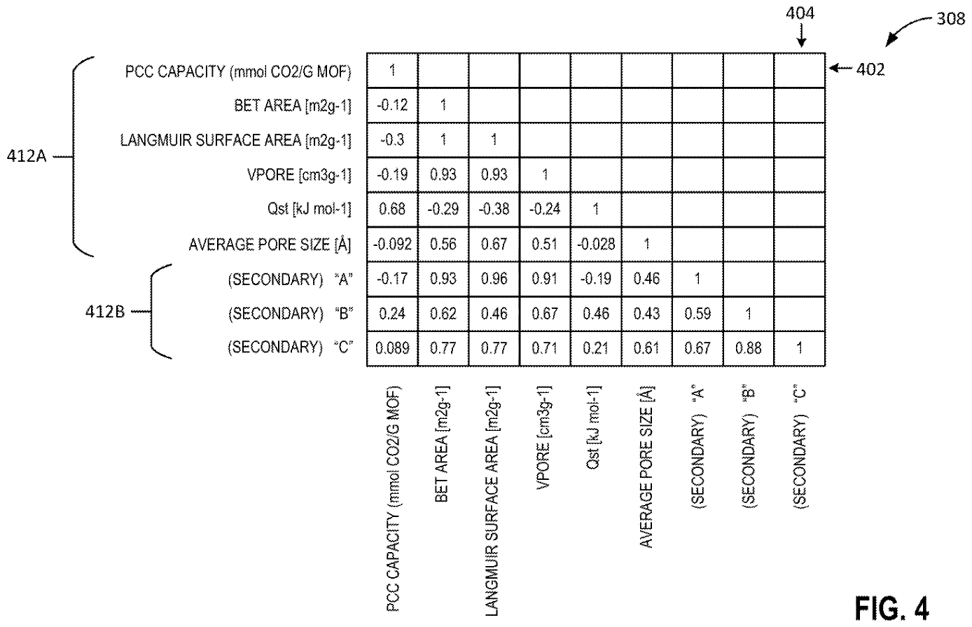

Additional details and related functions performed by the PCC modeling system 140 are described in greater detail as related to FIG. 3 and FIG. 4.

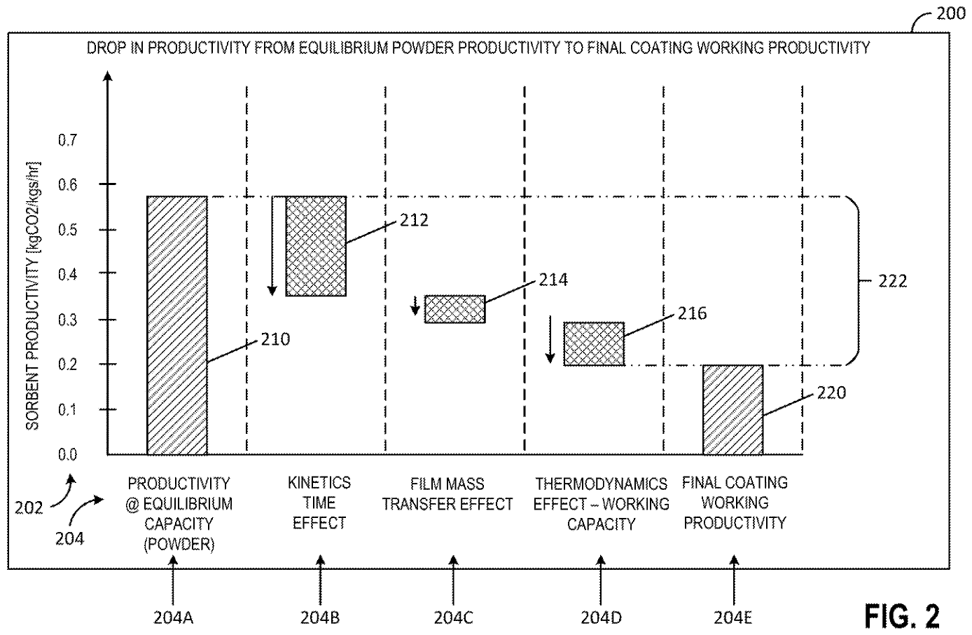

FIG. 2 is a graph 200 that illustrates a drop in CO₂ adsorptive productivity for an example sorbent (e.g., an example MOF) when going from a synthesized powder measured under equilibrium conditions to a final film coating on a substrate measured under dynamic conditions. In the example embodiment, the Y-axis 202 of the graph 200 is the sorbent productivity of the MOF in kilograms of CO₂ (kgCO₂) per kilogram of sorbent (kgs) per hour (hr). The X-axis illustrates several stages 204 of PCC productivity between an equilibrium powder productivity of initial stage 204A through a kinetic time effect stage 204B, a film mass transfer effect stage 204C, a thermodynamics effect (working capacity between adsorption and desorption) stage 204D, to a final coating working productivity stage 204E. In this example, at the initial stage 204A, the sorbent exhibits a productivity of approximately 0.58 kgCO₂/kgs/hr in synthesized powder measured under equilibrium conditions. At each of the stages 204B-204E, the sorbent experiences various reductions in productivity based on the various effects described above. For example, at the kinetic time effect stage 204B, the sorbent may experience a production reduction 212 of approximately 0.2 down to a total of approximately 0.35 kgCO₂/kgs/hr. Additionally, for example, at the film mass transfer effect stage 204C, the sorbent may experience a second production reduction 214 of approximately 0.05 down to a total of just below approximately 0.3 kgCO₂/kgs/hr. Further, for example, at the thermodynamics effect working capacity stage 204D, the sorbent may experience a third production reduction 216 of approximately 0.1 down to a final coating working productivity 220 of approximately 0.2 kgCO₂/kgs/hr. As such, in this example, the sorbent may experience a total productivity reduction 222 of approximately 0.38 kgCO₂/kgs/hr, or an approximately 65% reduction (e.g., approximately 35% utilization). This knockdown effect is specific for each sorbent, film coating, and cycle time operation.

The exhibited drop in PCC productivity of the example sorbent of FIG. 2 generally depends on the coating type and the measurement type properties, and can be due to a combination of multiple factors such as kinetics of cycle time for adsorption not allowing for equilibrium to be achieved, coating mass transfer resistance, and isosteric heat of adsorption heating the sorbent and reducing performance capacity. Without the PCC modeling system 140 of FIG. 1, all of these factors are generally experimentally determined in order to understand the final productivity of a given sorbent.

For the initial sorption at low concentration, the Henry's Law constant determines the equilibrium capacity of the sorbent. The sorbent capacity of the sorbent i, Nᵢ, is a function of the Henry's Law constant, Hᵢ, multiplied by the gas phase concentration of the sorbent, Cᵢ, as: Nᵢ=HᵢCᵢ. The larger the value of the Henry's constant, the steeper the initial slope of the isotherm. This means that a sorbent with a higher Hᵢ has a larger capacity for the sorbate in this low concentration linear region of the isotherm. Maximizing the Hᵢ also increases the productivity of the sorbent at low gas phase sorbate concentrations. As such, the PCC modeling system 140 will look to find sorbents with high Henry's Law constants for CO₂ adsorption by analyzing how the various MOF constituents independently vary with the Henry's constant. Since the Henry's constant is a thermodynamic term (e.g., not a kinetic term), the kinetics of the sorbent may also be evaluated in order to determine sorbent productivity. These measurements are not typically reported in the literature of known MOFs, and as such, this PCC modeling system 140 may look first at the Henry's constant to identify MOF constituents with the potential for the highest capacity of CO₂ at the lowest gas phase concentration of CO₂. Where kinetic uptake data are available, they are used as data inputs to the PCC modeling system.

FIGS. 3A-3C are a flow chart illustrating an example method 300 for analyzing anticipated performance for prospective sorbents in post-combustion carbon capture systems. In some embodiments, the method 300 may be performed by the PCC modeling system 140 and the identified sorbents may be installed within the PCC system 120 of FIG. 1. In the example embodiment, the method 300 includes collecting or otherwise identifying model training data for known sorbents (e.g., MOFs for which there is known performance data) at operation 310.

The identified model training data, in example embodiments, includes instances of individual sorbents and their particular composures and known performance data stored in a database such as the model data database (e.g., various variables for particular known sorbents). Each sorbent may include information on constituents of that particular sorbent instance (e.g., a particular metal, organic linker, and/or functional groups or functionalities), various physical features of the sorbent instance (e.g., pore size, pore volume, isometric heat of adsorption, Henry's Law constant, selectivity ratio, Langmuir/BET area, uptake rate, or the like), known performance data for the sorbent instance (e.g., PCC capacity and productivity), and perhaps other information on the sorbent instance, such as a unique identifier or other sorbent data (e.g., physisorbent or chemisorbent classification). Metals can include, for example, nickel, chromium, magnesium, copper, manganese, zirconium, zinc, cobalt, indium, iron, aluminum, dysprosium, titanium, potassium, or the like, or some combination or alloy). Organic linkers can include, for example, 1,4-dioxido-2,5-Benzenedicarboxylate (DOBDC), 1,4-benzene-dicarboxylate (BDC), 4,4′-oxido-1,1′-biphenyl-3,3′-dicarboxylate (DOBPDC), 1,3,5-tri (1H-1,2,3-trizol-4-yl)benzene) (BTTri), 1,3,5-benzene tricarboxylate (BTC), 1H,5H-benzo (1,2-d: 4,5-d′)bistriazole (BBTA), 1,1′-Biphenyl-4,4′-dicarboxylate (BPDC), 1,1′-biphenyl-3,3′,5,5′-tetracarboxylate (BPTC), 1,5-dioxido-2,6-naphthalenedicarboxylate (DONDC), 1,2,4,5-benzene-tetra-carboxylate (BTEC), 1,4-bix (1H-pyrazol-4-ylethynyl)benzene (BPEP), 2,5-di(1H-1,2,4-triazol-1-yl) terephthalate (BTTA), 2,4,6-tris(3,5-dicarboxylphenylamino)-1,3,5-triazine (TDPAT), 2,3,5,6-tetrachloo terephthalate (TCDC), 4,4′-dibenzoic acid-2,2′sulfone (SBPDC), or the like. Functionalities can include, for example, Open Metal Sites [OMS], Microporosity [MP], Lewis Basic Site [LBS], Polar Functional Site [PFS], Post Synthetic Modifications [PSM], or the like. While example metals, linkers, functional groups, and physical features are provided here, it should be understood that others are possible and within the scope of this disclosure. In some situations, such model training data of sorbents may be collected and recorded in the model data database manually (e.g., by the analyst 102). In some embodiments, the PCC modeling system 140 may be configured to collect such data (e.g., via other online databases, from performance or testing data captured via the PCC system 120, or the like).

This sorbent data is used by the PCC modeling system 140, in the example embodiment, as model training data for training a machine learning model to analyze anticipated performance of prospective sorbents (e.g., novel combinations of metals, linkers, and functionalities not already studied and tested in real-world conditions). This model training data can be used as labeled training data in model construction (e.g., instances of model training data of particular “inputs” having a known result or “label”). In some embodiments, one subset of the model training data may be identified for purposes of training the model and another subset may be identified for purposes of testing the model (e.g., 60% of sorbents being identified for training and 40% being identified for testing, 70% being identified for training and 30% being identified for testing, or the like). In some embodiments, the analyst 102 may manually identify the sorbents to use for training and testing (e.g., by particular rows of the database). In some embodiments, the PCC modeling system 140 may automatically identify the training subset and the testing subset (e.g., using preconfigured percentages, randomly selected, or the like).

In some embodiments, the method 300 also includes performing aspects of univariate data analysis on the model training data at operation 320. This data analysis includes evaluating particular individual sorbent variables (e.g., a particular constituent or feature) relative to other variables (e.g., another constituent, feature, or performance value) across the body of training data. This analysis can be used to identify high level trends relative to the particular constituents or features.

In the example embodiment, the PCC modeling system 140 may provide the analyst 102 with a graphical user interface that displays plots of particular features against other target features of interest, thereby allowing the analyst 102 to investigate trends and relations between those particular features. The interface may allow the analyst 102 to select a primary variable (e.g., as a domain) and a secondary variable (e.g., as a range) of interest and the PCC modeling system 140 may then compute, across all of the training data having those variables, average/mean/median values and/or ranges of values for a bar chart, forest plot, or the like (e.g., for a domain variable with discrete values with a continuous secondary variable), or may generate a scatterplot or the like (e.g., for continuous primary and secondary variables). For example, the PCC modeling system 140 may generate a plot of organic linkers versus isosteric heat of adsorption or Henry's Law constant or average pore size, and may separately identify physisorbents or chemisorbents (e.g., via distinct colors or shading). In another example, the PCC modeling system 140 may generate a plot of metals identified in the training data against isosteric heat of adsorption or a selectivity ratio.

At operation 330, in the example embodiment, the PCC modeling system 140 generates secondary features to use during model training. Secondary features are a combination of two or more primary features. The term “primary feature” refers to one of the known variables (e.g., pre-existing main effects parameters for the historical sorbent), such as isosteric heat of adsorption, Henry's Law constant, pore size, pore volume, surface area, or the like. The term “secondary feature” refers to a combination of two or more of those primary features that involves an interaction between the two primary features (e.g., an interaction parameter). In some embodiments, the analyst 102 may manually create, within the PCC modeling system 140, a secondary feature by designating two or more primary features to be combined as a new secondary feature of the model. In one example, a secondary feature “A” may be created as (BET area*Pore Volume (Vₚₒᵣₑ)), a secondary feature “B” as (Vₚₒᵣₑ*isosteric heat of adsorption (Qₛₜ)), and a secondary feature “C” as (BET area*Qₛₜ). These secondary features may be used in the model training and analysis described below.

In some embodiments, the PCC modeling system 140 may select secondary features to use during model training by used an automated selection process. For example, the PCC modeling system 140 may analyze the statistical significance of each of the primary features, such as via a probability value. The probability value (p-value) is a measure of the significance of a variable to the model. A p-value less than 0.05 means that the factor in the model is statistically significant with 95% confidence, which indicates strong evidence against the results being random, with less than a 5% probability that the results are random.

In some embodiments, the PCC modeling system 140 may select a set number of secondary features. For example, for n as the number of primary features analyzed by the PCC modeling system 140, the set number of secondary features may be ⁿC. In this example, a total number of primary and secondary features equal to (n+ⁿC.) may be automatically selected by the PCC modeling system 140.

At operation 340, in the example embodiment, the PCC modeling system 140 performs correlation and bivariate analysis of the model data. Referring now to FIG. 3B, this analysis includes identifying a feature set for model training. At operation 342, a prospective feature set is identified for model training. This feature set includes a list of primary features 302 (or first order features) and secondary features 304 (or second order features) to be used in the model training. As described above, the primary features 302 include a list of physical features or known variables that are provided for sorbents in the model data 160 (e.g., heat of adsorption, pore size, pore volume, Henry's constant, and the like), and the secondary features 304 include those combined features defined in operation 330. The primary and secondary features 302, 304 are referred to collectively as the “feature set” 306 for the model training. In an example embodiment, the primary features 302 include PCC capacity, BET area, Langmuir surface area, pore volume (Vₚₒᵣₑ), isosteric heat of adsorption (Qₛₜ), and average pore size (Å), and the secondary features 304 include the three example secondary features mentioned above, namely “A”=(BET area*Pore Volume (Vₚₒᵣₑ)), “B”=(Vₚₒᵣₑ*isosteric heat of adsorption (Qₛₜ)), and “C”=(BET area*Qₛₜ). As such, the training data can be considered as defining an n-dimensional space, where n is the number of features 306 used in the model training.

At operation 344, the PCC modeling system 140 may generate pair plots or scatter plots for each unique combination of the primary and secondary features 302, 304 in the feature set 306, and using the selected training data sorbents from the model data 160. For example, the PCC modeling system 140 may generate a first pair plot showing BET area and PCC capacity over the training data, a second pair plot showing Langmuir surface area and PCC capacity over the training data, a third pair plot showing Vₚₒᵣₑ and PCC capacity over the training data, and so forth for each unique combination of features 306. The PCC modeling system 140 may display these plots in a graphical user interface for inspection and consideration by the analyst 102. For some combinations, these plots may help the analyst 102 identify whether there is any correlation between those two variables within the training data, whether that correlation is linear or non-linear, and whether it is a positive or negative correlation. Additionally, these plots may help the analyst 102 identify the variables within the training data that are statistically significant.

At operation 346, the PCC modeling system 140 generates a correlation matrix 308 of correlation coefficients for the various pairs of the primary and secondary features 302, 304 in the feature set 306. More specifically, in the example embodiment, the correlation matrix 308 is an n by n matrix, where each unique feature 302, 304 in the feature set 306 is assigned both a row and a column (e.g., a square, reflective matrix). Each cell of the matrix 308 represents some combination of two of the features 302, 304 in the feature set 306 (e.g., based on the particular row and column of that cell), and the value contained in that cell is a correlation coefficient that represents a degree or magnitude of correlation between those two particular features. For each combination of two features 302, 304, the PCC modeling system 140 computes a correlation coefficient for those two features (e.g., across the training data) at operation 348. Correlation coefficients, in the example embodiment, are normalized from a range between +1.0 and −1.0, with more positive correlations between the two features being closer to +1.0, more negative correlations being closer to −1.0, and neutral (e.g., weak or non-existent) correlations being closer to 0.0 (e.g., a Pearson's correlation coefficient). At operation 350, the PCC modeling system 140 populates the particular cell(s) with the correlation coefficient associated with those two features 302, 304. Upon completion, this correlation matrix and associated values may be displayed to the analyst 102 for inspection and consideration, and in some embodiments may be presented as a heat map (e.g., coloring each individual cell based on its value), thus allowing the analyst 102 to more easily see positive and negative correlations between particular features. Additional details regarding an example correlation matrix 308 is provided as related to FIG. 4.

Returning again to FIG. 3A, the example method 300 continues at operation 360, where the PCC modeling system 140 performs regression analysis to generate a transfer function that can help approximate PCC performance of other (e.g., untested) sorbents. More specifically, FIG. 3C illustrates an example regression analysis process of operation 360.

In the example embodiment, a set of model training data is identified from the model data 160 for use during the regression operation 360. In some embodiments, and as described above, the particular instances of training data may be manually identified (e.g., by the analyst 102) or may be selected by the PCC modeling system 140 (e.g., automatically). The training data thus represents which known sorbents are within the scope of this particular regression analysis, where the remaining model data may be used to verify the results of this training.

At operation 364, a set of features are selected (e.g., from the primary and secondary features 302, 304 of the full feature set 306) for an initial feature set 380. In some embodiments, all of the features of the full feature set 306 may be initially used as the initial feature set 380. In other embodiments, the analyst 102 may manually select the features in the initial feature set 380 (e.g., based on reviewing the pair plots and/or correlation matrix). In still other embodiments, the PCC modeling system 140 may automatically select the initial feature set 380. For example, the PCC modeling system 140 may selectively add all features 302, 304 to the initial feature set 380 that have a correlation coefficient with the PCC capacity above a predetermined threshold (e.g., greater than 0.2), or below a predetermined threshold (e.g., less than −0.2). A number of these features, f, are then used as a current feature set 382 to begin the regression.

At operation 366, the PCC modeling system 140 performs multiple linear regressions on the model training data using the current feature set (e.g., using an ordinary least-squared model fit of the training data, where the PCC productivity is the dependent variable of interest, as determined based on PCC capacity and the CO₂ uptake rate (e.g., adsorption kinetics)). Here, a linear regression method is applied to Eq. 1 to study the dependence between the parameter of interest (e.g., the PCC capacity, Å) and the various physical attributes selected for the initial feature set 380 (e.g., BET area, pore volume, isosteric heat, and the second order features “A”, “B”, and “C” described above):

$$Å = {b}_{0} + {b}_{1} {X}_{1} + {b}_{2} {X}_{2} + ⋯ + {b}_{p} {X}_{p} \qquad Eq . 1$$

In this regression, each of the f current features 382 are represented in Eq. 1 by Xᵢ, along with an associated linear coefficient bᵢ. At first, all initial features 380 are included in the transfer function of Eq. 1 as the regression iterates, then the current feature 382 with the highest p-value is eliminated until all current features 382 have a p-value of less than a predetermined value (e.g., less than 0.05 meaning they have a 95% probability of being statistically significant). The relevant variables in the model are those that have a probability value (“p-value”) less than the predetermined threshold.

More specifically, in the example embodiment, at each step in the iteration, p-values are generated for each feature remaining in the set of current features 382. At test 368, the PCC modeling system 140 tests whether the regression is complete by evaluating the p-values of the current features 382. If all of the p-values of the remaining current features 382 are below the predetermined threshold, the iteration terminates. Otherwise, the iteration continues to operation 370. At operation 370, the PCC modeling system 140 identifies the current feature having the highest p-value and removes that particular feature from the current features 382 for the next iteration. The regression process returns to operation 366, continuing on with a reduced current feature set 382, again generating new p-values until all remaining features are below the predetermined threshold. If a primary feature has a p-value above the threshold, but a secondary feature that includes the primary feature has a p-value below the threshold, then the primary feature is kept as part of the model, even though it's individual p-value is larger than the threshold. This is necessary in order to keep the secondary feature with p-value below the threshold as part of the model.

Upon completion and exit of the regression iterations, the PCC modeling system 140 may have identified one or more remaining features to be included in a final feature set 384, each of which has a p-value at or below the predetermined threshold and is therefore statistically significant. In the example embodiment, the PCC modeling system 140 inspects the final results for possible indications of overfitting in the model. For the final feature set 384, the PCC modeling system 140 also generates an r-squared and adjusted r-squared value, and the difference between these two values can be an indication of overfitting (e.g., if they are too far apart). If the difference between the r-squared and adjusted r-squared values (e.g., abs(r-squared-adjusted r-squared)) is greater than a predetermined threshold, then there are chances of overfitting in the model. In such situations, the PCC modeling system 140 then analyzes each unique combination of the remaining features in the final feature set 384, runs the model with that combination to generate r-squared and adjusted r-squared values for each combination, and then selects the particular combination that has the closest r-squared and adjusted r-squared values (e.g., the smallest abs(r-squared-adjusted r-squared)).

The remaining features and their associated values are used to generate a final transfer function from this model. More specifically, the regression yields a final coefficient for each of the remaining features in the final feature set 384, as well as a constant coefficient (e.g., y-intercept value). As such, each of the X_{f} variables of Eq. 1 are identified with each of the remaining features, and each associated coefficient b_{f} is added into Eq. 1, as well as the constant coefficient b₀, to generate the final transfer function. As such, this transfer function can be used with prospective sorbents and their associated values to determine an anticipated PCC capacity of that particular sorbent.

In some embodiments, the PCC modeling system 140 may use the model on test data to evaluate how it performs in predictive capability. For example, the PCC modeling system 140 may generate a residual plot for the linear regression model for both the training data and the test data, thereby allowing the analyst 102 to evaluate how well the model performs.

In one particular example, a regression operation 360 is performed on an example training set starting with an initial feature set of isosteric heat of adsorption (Qₛₜ), BET area, Pore Volume (Vₚₒᵣₑ)), and the three example secondary features “A”, “B”, and “C”. At a first iteration, the p-value of BET area is identified as the highest at 0.948 and is removed. At a second iteration, the p-value of the “A” secondary feature is identified as the highest at 0.769 and is removed. At a third iteration, the p-value of the “B” secondary feature is identified as the highest at 0.441 and is removed. At a fourth iteration, the p-values of all of the remaining current features (e.g., Qₛₜ, Vₚₒᵣₑ, and the “C” secondary feature) are below 0.05, and thus the regression iteration terminates with these three features as the final feature set. However, in this example, the final r-squared value is 0.400 and the adjusted r-squared value is 0.363, a difference which triggers analysis for overfitting. Since there are three remaining features in the final feature set 384, each combination of those features is inspected with the model (e.g., a total of 3!=6 unique combinations, namely [Qₛₜ], [Qₛₜ, Vₚₒᵣₑ], [Qₛₜ, Vₚₒᵣₑ, “C”], [Vₚₒᵣₑ], [Vₚₒᵣₑ, “C”], and [“C”]). In this example, the combination of just [Qₛₜ] yields an r-squared of 0.567 and an adjusted r-squared of 0.560, for the smallest difference of 0.007. As such, only the Qₛₜ feature and its associated values are used to generate the final transfer function with only the one remaining feature (e.g., X₁=Qₛₜ), namely Å=b₁X₁+b₀=0.0318*Qₛₜ−0.4243, where b₁=0.0318 is the final coefficient generated for Qₛₜ and where b₀=−0.4243 is the constant coefficient. Applying test data to the trained model, in this particular example, yielded a test r-squared value of 0.331, where the r-squared of the trained model was 0.567. As such, the equation includes only features for which the p-value is less than 0.05. Further, the positive r-square of the test data is indicates that the model is able to explain about 60% of the capacity using the heat of adsorption (Qₛₜ).

The PCC modeling system 140 may use the generated transfer function to operate a post combustion carbon capture system, such as, but not limited to, by determining the one or more prospective sorbents to be used by the post combustion carbon system. For example, the PCC modeling system 140 may identify one or more prospective sorbents based on a carbon capture performance value as determined by the transfer function to facilitate improving the overall carbon capture performance of the post combustion carbon capture system.

FIG. 4 illustrates an example correlation matrix 308. In some embodiments, the correlation matrix 308 is generated by the PCC modeling system 140 and used in the method 300 described in FIGS. 3A-3C. In the example embodiment, the correlation matrix 308 is a 9×9 square, reflective matrix. There are nine rows 402 and nine columns 404, as well as nine features 412 that are the subjects of this example model. Each of the nine features 412 has both an associated row 402 and an associated column 404. The features 412 include six first order (“primary”) features 412A and three second order (“secondary”) features 412B, similar to the examples provided in FIGS. 3A-3C. Each cell of the matrix includes a correlation coefficient that is computed between the two particular intersecting features of that cell. For example, the correlation coefficient between BET area and PCC capacity is −0.12.

The methods, systems, and compositions disclosed herein are not limited to the specific embodiments described herein, but rather, steps of the methods, elements of the systems, and/or elements of the compositions may be utilized independently and separately from other steps and/or elements described herein. For example, the methods, systems, and compositions are not limited to practice with only a rotary machine as described herein. Rather, the methods, systems, and compositions may be implemented and utilized in connection with many other applications.

Although specific features of various embodiments may be shown in some drawings and not in others, this is for convenience only. Moreover, references to “one embodiment” in the above description are not intended to be interpreted as excluding the existence of additional embodiments that also incorporate the recited features. In accordance with the principles of the disclosure, any feature of a drawing may be referenced and/or claimed in combination with any feature of any other drawing.

This written description uses examples, including the best mode, to enable any person skilled in the art to practice the disclosure, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

Further aspects of the invention are provided by the subject matter of the following clauses:

A power generation system comprising: a capture system for use in capturing carbon dioxide; a controller configured to operate the capture system; and a modeling system including a processor configured to: identify a model training data set, each instance of the model training data set identifying a sorbent used by the capture system, a carbon capture performance value for the sorbent, and a plurality of primary feature values associated with a plurality of primary features; generate one or more secondary features based on one or more of the plurality of primary features, each of the one or more secondary features being a combination of at least two of the plurality of primary features; determine a plurality of correlation magnitude values including a correlation magnitude value between each of the plurality of primary features and each of the one or more secondary features; identify a first subset of the model training data set based on the plurality of correlation magnitude values; determine a statistical significance for each instance of the first subset of the model training data set; identify a second subset of the model training data set based on the statistical significance, wherein the statistical significance for each instance of the second subset of the model training data set is below a pre-determined threshold; generate a transfer function based on the second subset of the model training data set; and determine, using the transfer function, one or more prospective sorbents to be used by the capture system based on the carbon capture performance value, wherein the controller operates the capture system using the one or more prospective sorbents determined by the modeling system.

The power generation system in accordance with any of the preceding clauses, wherein generating the one or more secondary features based on one or more of the plurality of primary features comprises performing a univariate data analysis on the plurality of primary features.

The power generation system in accordance with any of the preceding clauses, wherein determining the plurality of correlation magnitude values comprises generating a correlation matrix comprising a plurality of cells, the plurality of cells being arranged in a plurality of rows and a plurality of columns for the plurality of primary features and the one or more secondary features with each of the plurality of cells including one of the plurality of correlation magnitude values.

The power generation system in accordance with any of the preceding clauses, wherein the processor of the modeling system is configured to select an initial feature set from the plurality of primary features and the one or more secondary features.

The power generation system in accordance with any of the preceding clauses, wherein selecting the initial feature set comprises receiving, from a user, user input indicating a selection of one or more features of the plurality of primary features and the one or more secondary features.

The power generation system in accordance with any of the preceding clauses, wherein selecting the initial feature set comprises selecting one or more features of the plurality of primary features and the one or more secondary features, each of the one or more features having a correlation coefficient greater than a predetermined threshold.

The power generation system in accordance with any of the preceding clauses, wherein each of the one or more features have one or more PCC performance data values greater than a predetermined threshold.

The power generation system in accordance with any of the preceding clauses, wherein the processor of the modeling system is configured to: determine an r-squared value and an associated adjusted r-squared value for each unique combination of each instance of the second subset of the model training data set; determine a difference value between the r-squared value and the associated adjusted r-squared value for each instance of the second subset of the model training data set; and identify a third subset of the model training data set based on the difference value, wherein the difference value for each instance of the third subset of the model training data set is greater than a predetermined difference value threshold.

The power generation system in accordance with any of the preceding clauses, wherein the difference value for each instance of the third subset of the model training data set is less than the predetermined difference value threshold.

The power generation system in accordance with any of the preceding clauses, wherein the plurality of primary features includes at least a carbon capture capacity and an isosteric adsorption heat value.

The power generation system in accordance with any of the preceding clauses, wherein the one or more secondary features are based on one or more of a selectivity ratio, a pore volume, and an isosteric adsorption heat value.

A method of selecting one or more prospective sorbents for use in operating a capture system to capture carbon dioxide, the method comprising: identifying a model training data set, each instance of the model training data set identifying a sorbent used by the capture system, a carbon capture performance value for the sorbent, and a plurality of primary feature values associated with a plurality of primary features; generating one or more secondary features based on one or more of the plurality of primary features, each of the one or more secondary features being a combination of at least two of the plurality of primary features; determining a plurality of correlation magnitude values including a correlation magnitude value between each of the plurality of primary features and each of the one or more secondary features; identifying a first subset of the model training data set based on the plurality of correlation magnitude values; determining a statistical significance for each instance of the first subset of the model training data set; identifying a second subset of the model training data set based on the statistical significance, wherein the statistical significance for each instance of the second subset of the model training data set is below a pre-determined threshold; generating a transfer function based on the second subset of the model training data set; and determining, using the transfer function, one or more prospective sorbents to be used by the capture system based on the carbon capture performance value, wherein a controller operates the capture system using the one or more prospective sorbents determined using the transfer function.

The method in accordance with any of the preceding clauses, wherein generating the one or more secondary features based on one or more of the plurality of primary features comprises performing a univariate data analysis on the plurality of primary features.

The method in accordance with any of the preceding clauses, wherein determining the plurality of correlation magnitude values comprises generating a correlation matrix comprising a plurality of cells, the plurality of cells being arranged in a plurality of rows and a plurality of columns for the plurality of primary features and the one or more secondary features with each of the plurality of cells including one of the plurality of correlation magnitude values.

The method in accordance with any of the preceding clauses, further comprising selecting an initial feature set from the plurality of primary features and the one or more secondary features.

The method in accordance with any of the preceding clauses, wherein selecting the initial feature set comprises receiving, from a user, user input indicating a selection of one or more features of the plurality of primary features and the one or more secondary features.

The method in accordance with any of the preceding clauses, wherein selecting the initial feature set comprises selecting one or more features of the plurality of primary features and the one or more secondary features, each of the one or more features having a correlation coefficient greater than a predetermined threshold.

The method in accordance with any of the preceding clauses, further comprising: determining an r-squared value and an associated adjusted r-squared value for each unique combination of each instance of the second subset of the model training data set; determining a difference value between the r-squared value and the associated adjusted r-squared value for each instance of the second subset of the model training data set; and identifying a third subset of the model training data set based on the difference value.

The method in accordance with any of the preceding clauses, wherein identifying the third subset of the model training data comprises the difference value for each instance of the third subset of the model training data set being greater than a predetermined difference value threshold.

The method in accordance with any of the preceding clauses, wherein identifying the third subset of the model training data comprises the difference value for each instance of the third subset of the model training data set being less than a predetermined difference value threshold.

While the invention has been described in terms of various specific embodiments, those skilled in the art will recognize that the invention can be practiced with modification within the spirit and scope of the claims.

What is claimed is:

1. A power generation system comprising:
a capture system for use in capturing carbon dioxide;
a controller configured to operate the capture system; and
a modeling system including a processor configured to:
identify a model training data set, each instance of the model training data set identifying a sorbent used by the capture system, a carbon capture performance value for the sorbent, and a plurality of primary feature values associated with a plurality of primary features;
generate one or more secondary features based on one or more of the plurality of primary features, each of the one or more secondary features being a combination of at least two of the plurality of primary features;
determine a plurality of correlation magnitude values including a correlation magnitude value between each of the plurality of primary features and each of the one or more secondary features;
identify a first subset of the model training data set based on the plurality of correlation magnitude values;
determine a statistical significance for each instance of the first subset of the model training data set;
identify a second subset of the model training data set based on the statistical significance, wherein the statistical significance for each instance of the second subset of the model training data set is below a pre-determined threshold;
generate a transfer function based on the second subset of the model training data set; and
determine, using the transfer function, one or more prospective sorbents to be used by the capture system based on the carbon capture performance value;
wherein the controller operates the capture system using the one or more prospective sorbents determined by the modeling system.

2. The power generation system of claim 1, wherein generating the one or more secondary features based on one or more of the plurality of primary features comprises performing a univariate data analysis on the plurality of primary features.

3. The power generation system of claim 1, wherein determining the plurality of correlation magnitude values comprises generating a correlation matrix comprising a plurality of cells, the plurality of cells being arranged in a plurality of rows and a plurality of columns for the plurality of primary features and the one or more secondary features with each of the plurality of cells including one of the plurality of correlation magnitude values.

4. The power generation system of claim 1, wherein the processor of the modeling system is configured to select an initial feature set from the plurality of primary features and the one or more secondary features.

5. The power generation system of claim 4, wherein selecting the initial feature set comprises receiving, from a user, user input indicating a selection of one or more features of the plurality of primary features and the one or more secondary features.

6. The power generation system of claim 4, wherein selecting the initial feature set comprises selecting one or more features of the plurality of primary features and the one or more secondary features, each of the one or more features having a correlation coefficient greater than a predetermined threshold.

7. The power generation system of claim 6, wherein each of the one or more features have one or more PCC performance data values greater than a predetermined threshold.

8. The power generation system of claim 1, wherein the processor of the modeling system is configured to:
determine an r-squared value and an associated adjusted r-squared value for each unique combination of each instance of the second subset of the model training data set;
determine a difference value between the r-squared value and the associated adjusted r-squared value for each instance of the second subset of the model training data set; and
identify a third subset of the model training data set based on the difference value, wherein the difference value for each instance of the third subset of the model training data set is greater than a predetermined difference value threshold.

9. The power generation system of claim 8, wherein the difference value for each instance of the third subset of the model training data set is less than the predetermined difference value threshold.

10. The power generation system of claim 1, wherein the plurality of primary features includes at least a carbon capture capacity and an isosteric adsorption heat value.

11. The power generation system of claim 1, wherein the one or more secondary features are based on one or more of a selectivity ratio, a pore volume, and an isosteric adsorption heat value.

12. A method of selecting one or more prospective sorbents for use in operating a capture system to capture carbon dioxide, the method comprising:
identifying a model training data set, each instance of the model training data set identifying a sorbent used by the capture system, a carbon capture performance value for the sorbent, and a plurality of primary feature values associated with a plurality of primary features;
generating one or more secondary features based on one or more of the plurality of primary features, each of the one or more secondary features being a combination of at least two of the plurality of primary features;
determining a plurality of correlation magnitude values including a correlation magnitude value between each of the plurality of primary features and each of the one or more secondary features;
identifying a first subset of the model training data set based on the plurality of correlation magnitude values;
determining a statistical significance for each instance of the first subset of the model training data set;
identifying a second subset of the model training data set based on the statistical significance, wherein the statistical significance for each instance of the second subset of the model training data set is below a pre-determined threshold;
generating a transfer function based on the second subset of the model training data set; and
determining, using the transfer function, one or more prospective sorbents to be used by the capture system based on the carbon capture performance value, wherein a controller operates the capture system using the one or more prospective sorbents determined using the transfer function.

13. The method of claim 12, wherein generating the one or more secondary features based on one or more of the plurality of primary features comprises performing a univariate data analysis on the plurality of primary features.

14. The method of claim 12, wherein determining the plurality of correlation magnitude values comprises generating a correlation matrix comprising a plurality of cells, the plurality of cells being arranged in a plurality of rows and a plurality of columns for the plurality of primary features and the one or more secondary features with each of the plurality of cells including one of the plurality of correlation magnitude values.

15. The method of claim 12, further comprising selecting an initial feature set from the plurality of primary features and the one or more secondary features.

16. The method of claim 15, wherein selecting the initial feature set comprises receiving, from a user, user input indicating a selection of one or more features of the plurality of primary features and the one or more secondary features.

17. The method of claim 15, wherein selecting the initial feature set comprises selecting one or more features of the plurality of primary features and the one or more secondary features, each of the one or more features having a correlation coefficient greater than a predetermined threshold.

18. The method of claim 12, further comprising:
determining an r-squared value and an associated adjusted r-squared value for each unique combination of each instance of the second subset of the model training data set;
determining a difference value between the r-squared value and the associated adjusted r-squared value for each instance of the second subset of the model training data set; and
identifying a third subset of the model training data set based on the difference value.

19. The method of claim 18, wherein identifying the third subset of the model training data comprises the difference value for each instance of the third subset of the model training data set being greater than a predetermined difference value threshold.

20. The method of claim 18, wherein identifying the third subset of the model training data comprises the difference value for each instance of the third subset of the model training data set being less than a predetermined difference value threshold.
